(19) United States
(12) Patent Application Publication
(10) Pub. No.: US 2026/0190507 A1
(43) Pub. Date: Jul. 2, 2026

(54) PHOTODIODE AND METHOD OF FABRICATING SAME

(71) Applicant: XANADU QUANTUM TECHNOLOGIES INC., Toronto (CA)

(72) Inventor: Xiangwen GUO, Toronto (CA)

(21) Appl. No.: 19/535,846

(22) Filed: Feb. 10, 2026

Related U.S. Application Data
(60) Provisional application No. 63/740,458, filed on Dec. 31, 2024.

(51) Int. Cl. H10F 30/223; G02B 6/13; H10F 71/00; H10F 77/40

(52) U.S. Cl. CPC H10F 30/223; G02B 6/131; H10F 71/1272; H10F 77/413

(57) ABSTRACT

There is described a photodiode having a p-doped semiconductor layer, an n-doped semiconductor layer, and an intrinsic layer forming a PIN junction of the photodiode. The photodiode further comprises a multifunctional layer of materials such as InGaAsP or InGaAsAl formed on top of the p-doped semiconductor layer that (1) functions as a contact layer between the p-doped semiconductor layer and one or more metal contacts formed thereon and (2) is configured to minimize photon absorption at a target wavelength range. In some embodiments of the photodiode that are in a p-down configuration, the multifunctional layer may further serve as an etch stop layer that does not need to be removed after etching thereby simplifying the fabrication process of the device.

### CROSS-REFERENCE TO RELATED APPLICATIONS

This application claims priority from U.S. Provisional Patent Application No. 63/740,458 filed on Dec. 31, 2024, the entire contents of which are incorporated by reference herein.

### BACKGROUND OF THE INVENTION

The present application relates to optoelectronic semiconductor devices, and in particular to a photodiode that converts an optical signal to an electrical signal and a method of fabricating the same.

In wafer fabrication, heterogeneous integration is used to combine components formed on different material platforms onto a single photonic chip, thus minimizing loss stemming from off-chip coupling. This method of semiconductor fabrication is of particular interest in the manufacturing of photodiodes used in quantum photonic applications as they offer on-chip photonic detection capabilities.

A technique known as bonding may be used to carry out heterogeneous integration. During bonding, unpatterned wafer/die is combined with patterned photonic chips by forming chemical bonds at the material interface, permitting the concurrent fabrication of multiple devices. This requires removal of the native substrate of the wafer material, which is usually achieved with a chemical wet etching process. In order to stop the etch and prevent damage to the epitaxial material of the wafer, an etch stop layer that is highly selective to the substrate material is typically used. For example, indium gallium arsenide (InGaAs) is a typical etch stop material for InP substrate removal. However, because the etch stop layer material, such as InGaAs, may absorb light at wavelengths of interest, carriers generated in the etch stop layer cannot be collected efficiently, thus introducing additional loss.

It is therefore desirable to provide an improved photodiode that at least partially addresses one or more of the concerns above.

### SUMMARY OF THE INVENTION

In one aspect, there is provided a photodiode comprising: a first layer of a first type semiconductor; a second layer of a second type semiconductor; a third intrinsic layer between the first and second layers; and a fourth multifunctional layer formed above the first layer, wherein the fourth multifunctional layer (1) functions as a contact layer between the first layer and one or more metal contacts and (2) is configured to minimize photon absorption at a target wavelength range.

In another aspect, there is provided a method comprising: fabricating a photonic waveguide platform; growing an epitaxial structure on a substrate, the epitaxial structure having a first semiconductor layer, a second semiconductor layer, a third intrinsic layer between the first and second semiconductor layers, and a fourth multifunctional layer directly below the first semiconductor layer, the fourth multifunctional layer configured to minimize photon absorption at a target wavelength range; integrating the epitaxial structure onto a surface of the photonic waveguide platform in an inverted fashion such that the substrate forms a top surface; removing the substrate through an etching process; forming a mesa structure from the epitaxial structure, a portion of the multifunctional layer remaining as a contact layer; and forming one or more contact elements on the mesa structure including at least one contact element on the multifunctional layer, the multifunctional layer functioning as a contact layer.

In any of the above aspects, a material of the fourth multifunctional layer may be one of InGaAsP and InGaAsAl.

In any of the above aspects, the composition of phosphorus (P) or aluminum (Al) in the fourth multifunctional layer material may be configured to achieve the target wavelength range.

In any of the above aspects, the first and second layers may be arranged in an n-down structure, and the fourth multifunctional layer also serves as an etch stop layer during a wet etching process.

In any of the above aspects, the target wavelength range may include 1260 nm to 1625 nm.

In any of the above aspects, the fourth multifunctional layer may maintain a lattice match with the first layer.

In any of the above aspects, the first type semiconductor may be a p-type doped semiconductor material and the second type semiconductor is an n-type doped semiconductor material.

In any of the above aspects, the photodiode may be coupled to a photonic waveguide platform, and the photonic waveguide platform includes a waveguide formed therein configured to direct a photonic signal towards the photodiode.

In any of the above aspects, the photodiode may be a III-V semiconductor mesa structure bonded on a top surface of the photonic waveguide platform.

In any of the above aspects, the first and second layers may be arranged in a p-down structure.

In any of the above aspects, the growing may include forming the fourth multifunctional layer out of one of InGaAsP and InGaAsAl.

In any of the above aspects, the growing may include forming the fourth multifunctional layer directly above the substrate, the etching process is a wet etching process, and the fourth multifunctional layer functions as an etch stop.

Any of the above aspects may further comprise forming a passivation layer over the mesa structure prior to the forming of the one or more contact elements.

In any of the above aspects, the growing may further include: forming the first semiconductor layer with a first type semiconductor; and forming the second semiconductor layer with a second type semiconductor.

In any of the above aspects, the first type semiconductor may be a p-type semiconductor and the second type semiconductor is an n-type semiconductor.

Any of the above aspects may further comprise forming a waveguide in the photonic waveguide platform, wherein the waveguide is configured to direct a photonic signal towards the epitaxial structure.

Any of the above aspects may further comprise configuring a chemical composition of the multifunctional layer to achieve the target wavelength range.

In any of the above aspects, the target wavelength range may include 1260 nm to 1625 nm.

In any of the above aspects, the growing may include forming the second semiconductor layer directly above the substrate.

### BRIEF DESCRIPTION OF DRAWINGS

Reference will now be made, by way of example, to the accompanying figures which show example embodiments of the present application, and in which:

FIGS. 1A and 1B respectively show the two possible epitaxial structures of a photodiode, p-down and n-down, that stem from two possible epitaxy layer arrangements of the PIN junction based on the positions of the p-type doped and n-type doped semiconductor layers relative to the waveguide underneath;

FIG. 2 illustrates a side elevation view of the epitaxial structure of an integrated photonic device in a p-down configuration in accordance with some embodiments of the present disclosure;

FIG. 3 illustrates a side elevation view of the epitaxial structure of an integrated photonic device in an n-down configuration in accordance with some embodiments of the present disclosure;

FIG. 4 illustrates a flowchart of a method of manufacturing an integrated photonic device, such as those shown in FIGS. 2 and 3, in accordance with an aspect of the present disclosure; and

FIGS. 5A-5E illustrate high-level conceptual illustrations of a photodiode device in accordance with the present disclosure at various stages of the method shown in FIG. 4.

Like reference numerals are used throughout the figures to denote similar elements and features. While aspects of the invention will be described in conjunction with the illustrated embodiments, it will be understood that it is not intended to limit the invention to such embodiments.

### DETAILED DESCRIPTION OF THE INVENTION

A photodiode is essentially a PIN structure comprising a p-type doped semiconductor and an n-type doped semiconductor separated by an intrinsic region. Upon absorption of a photon of sufficient energy, an electron-hole pair is created such that the positively charged holes and the negatively charged electrons are respectively directed to the anode and the cathode of the device by the built-in electrical field thereby producing a photocurrent. Accordingly, photodiodes are well-suited to provide photodetection capabilities in a semiconductor device.

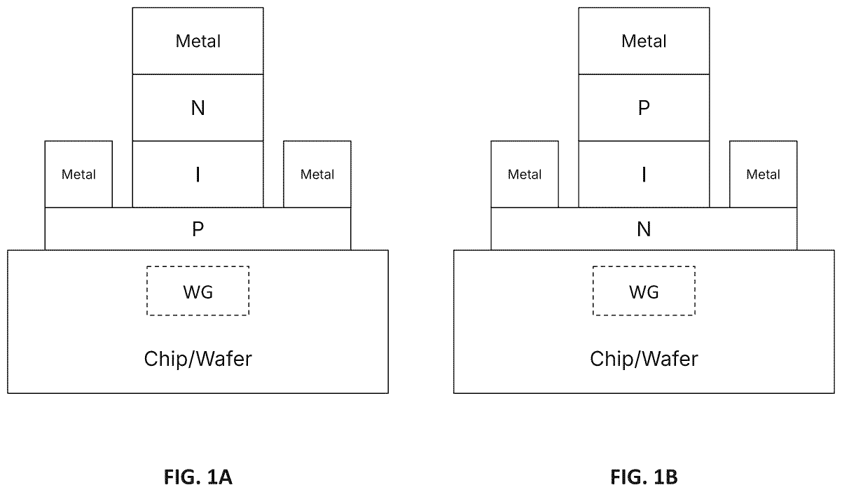

FIGS. 1A and 1B respectively show the two possible epitaxial structures of a photodiode, p-down and n-down, that stem from two possible epitaxy layer arrangements of the PIN junction based on the positions of the p-type doped and n-type doped semiconductor layers relative to the waveguide underneath. The term “semiconductor layer” generally refers to a horizontal epitaxial portion within the photodiode that is at least partially responsive to light/photons of a particular wavelength, thereby contributing to one or more of the photonic properties of the photodiode. As shown in FIG. 1A, in the p-down structure, the p-type doped semiconductor layer is further down in the epitaxial layer stack and is therefore closer to the waveguide WG formed within a photonic chip/wafer on top of a substrate. As shown in FIG. 1B, in the n-down structure, the n-type doped semiconductor layer is further down in the epitaxial layer stack and is therefore closer to the waveguide WG.

III-V semiconductors refer to a group of preferred semiconductor materials often used in the manufacturing of semiconductor photodiodes. III-V compounds are those created by combining elements from group III (e.g., B, Al, Ga, In) and group V (e.g., N, P, As, Sb) of the periodic table. Silicon, the most prominent semiconductor material, has an “indirect” bandgap, meaning that an excited electron must move through multiple pathways to reach its lowest energy state in the conduction band. In contrast, III-V semiconductors such as GaN, GaAs, and InP have a “direct” bandgap, providing these materials with the ability to absorb photons more efficiently. Further, the bandgap may be engineered to achieve desired values by configuring the chemical composition of the III-V semiconductor material. This makes III-V semiconductors well-suited for optoelectronic applications such as photodiodes.

In some embodiments, the photodiode described herein is a III-V semiconductor photodiode that comprises a plurality of semiconductor layers, including a multi-functional layer that not only improves the contact performance of the p-mesa contact structures formed thereon, but also whose material composition may be configured to achieve a desired bandgap to minimize photon absorption of the layer at particular wavelengths (and thereby lower optical loss).

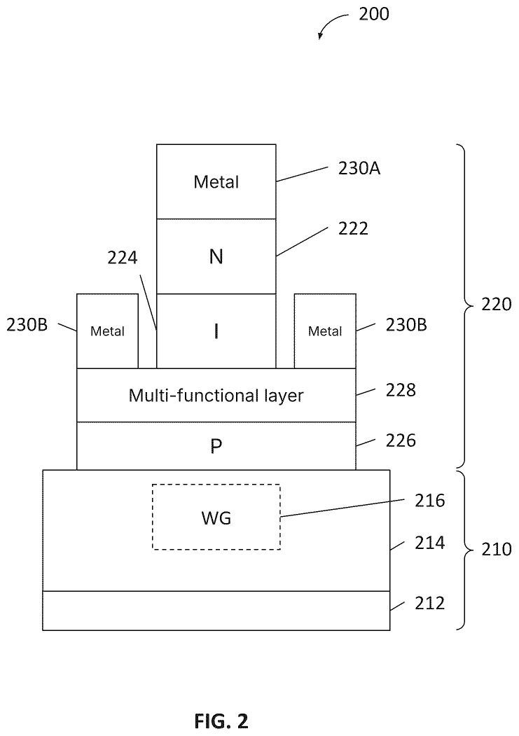

FIG. 2 illustrates a side elevation view of the epitaxial structure of an integrated photonic device 200 in a p-down configuration in accordance with some embodiments of the present disclosure. The dimensions of certain features may be exaggerated for illustrative purposes. The epitaxial structure in FIG. 2 includes a photodiode 220 supported on top of a photonic waveguide platform 210. In certain embodiments, the photodiode 220 is formed from a molecular die of group III-V material and is heterogeneously integrated onto the photonic waveguide platform 210 as described in more detail below. Such an approach permits the utilization of silicon wafer processing technology as well as the high performance and configurability of the III-V material in photonic applications.

The photonic waveguide platform 210 may be a multi-layer silicon wafer that includes a substrate 212 supporting a cladding layer 214, wherein a waveguide (WG) 216 is formed. The substrate 212 may be fabricated with any suitable material including silicon, diamond, gallium nitride (GaN), gallium arsenide (GaAs), and indium phosphide (InP) for example. The thickness of the substrate 212 may be dependent upon fabrication technology and/or application, typically ranging from 100 μm to 1000 μm. The photonic waveguide platform 210 may be configured to perform one or more photonic application functionalities.

The cladding layer 214 is supported on top of the substrate 212. Although a single instance of cladding layer 214 and waveguide 216 is shown in FIG. 2, it is understood that there may be multiple instances of each. At least one optical waveguide 216 is formed within the cladding layer 214. The cladding layer 214 may be of any suitable cladding material so as to provide a contrasting refractive index with the material of the waveguides 216 such that any transmitted mode is partially, substantially, or entirely confined by means of total internal reflection. By way of a non-limiting example, for a cladding layer 214 made of SiO₂, the optical waveguide 216 may be fabricated from SiN or lithium niobate (LN) to achieve total internal reflection with the selected cladding material. In some embodiments, the photonic waveguide platform 210 is a patterned wafer where one or more integrated circuit elements (not shown) such as modulators, resonators, directional couplers, and fiber-to-chip couplers may be fabricated by any suitable means such as etching (mechanical or chemical), engraving, bonding, and/or lithography. By way of a non-limiting example, the photonic waveguide platform 210 may be a thin film lithium niobate (TFLN) chip. The optical mode may be directed from the waveguide 216 and evanescently coupled to the photodiode 220 by any suitable means such as through an adiabatic tapered waveguide such as those described in U.S. Provisional Patent Application No. 63/613,131 , the disclosure of which is incorporated herein by reference in its entirety. Other known methods of directing optical signals towards a photodiode, such as grating couplers, may also be used.

In preferred embodiments, the bare die from which photodiode 220 is to be formed may be fabricated independently of the photonic waveguide platform 210 and integrated onto the photonic waveguide platform 210 via heterogeneous integration as described in more detail herein. FIG. 2 illustrates the photodiode 220 after integration onto the photonic waveguide platform 210.

The photodiode 220 includes a PIN junction formed by an n-type doped semiconductor layer 222, an intrinsic layer 224, and a p-type doped semiconductor layer 226. One or more optional layers, such as shielding layers and light-doped layers to prevent leakage current (not shown), may be present in the photodiode 220 without departing from the scope of the present disclosure. The embodiment shown in FIG. 2 is a vertically stacked configuration referred to as “p-down,” with the p-type doped semiconductor layer 226 closest to the waveguide 216. In some embodiments, the n-type doped semiconductor layer 222 is of indium phosphide (InP) doped with an n-type dopant, such as a group V element including silicon, phosphorus, arsenic, antimony, bismuth, and lithium with a doping concentration of approximately 6×10¹⁹ cm⁻³. The thickness of layer 222 may range from 50 to 1000 nm. In some embodiments, the p-type doped semiconductor layer 226 is of InP doped with a suitable p-type dopant, such as a group III element including zinc, beryllium, boron, aluminum, gallium, and indium with a doping concentration of approximately 5×10¹⁴ cm⁻³. The thickness of layer 226 may range from 50 to 1000 nm. The intrinsic layer 224 may be of undoped InP with layer thickness ranging from 50 to 1000 nm. In some embodiments, the intrinsic layer 224 may be subject to unintentional doping due to dopant diffusion from layers 222 and 226, resulting in doping concentrations ranging from 1×10¹³ to 1×10¹⁷ cm⁻³.

A multi-functional layer 228 is disposed on a top surface of the p-type doped semiconductor layer 226 with layer thickness ranging from 10 to 500 nm. For proper lattice matching, the multifunctional layer 228 may be doped with the same p-type dopant as layer 226 at concentrations ranging from 1×10¹⁷ to 6×10¹⁹ cm⁻³. In some embodiments, the material of the multi-functional layer 228 is selected to achieve lattice matching with the semiconductor layer on top of which it is formed. By way of a non-limiting example, in a preferred embodiment where the p-type doped semiconductor layer 226 is of InP, the multi-functional layer 228 is of any one of indium gallium arsenide phosphide (having a generic formula of InₓGa₁₋ₓAs_{y}P_{1-y} where 0<x, y<1, or InGaAsP for short), InGaAsAl, or InGaAs imbued with a suitable element. This matching of geometric lattice parameters permits the formation of a bandgap variation without introducing crystalline defects that degrade the optical properties of the device. The amount of lattice mismatch may be determined by comparing any of the lattice constants of the p-type doped semiconductor layer 226 with those of the multi-functional layer 228. The lattices are said to be matched if the lattice constants between two adjacent layers are approximately the same.

Further, the bandgap of an InGaAsP multi-functional layer may be configured by manipulating the chemical composition (x, y) of the InGaAsP to achieve a desired bandgap. The bandgap energy of InGaAsP may be correlated to the composition of phosphide (1-y) contained therein. By way of a non-limiting example, it may be desirable to minimize the absorption of photons having wavelengths within the C band (i.e., 1530 nm to 1565 nm). In some examples, it may be desirable to minimize the absorption of photons having wavelengths of approximately 1550 nm. In further example embodiments, the target wavelength may range from 1260 nm to 1625 nm. To this end, the composition of InₓGa₁₋ₓAs_{y}P_{1-y} may be varied, for example, by having a composition of P (1-y) in the range of 0.26 to 0.66.

In some embodiments, the multi-functional layer 228 may also function to improve upon the contact resistance of the p-mesa contacts 230B. With an elevated concentration of free carriers, n-type doped semiconductors typically exhibit higher conductivity than their p-type counterparts. On the other hand, p-type doped semiconductors possess an excess of positively charged holes, resulting in a lower conductivity compared to n-type. For example, n-type dopants phosphorus, arsenic, and antimony exhibit charge carrier mobilities of 1500 cm²/Vs, 1200 cm²/Vs, and 500 cm²/Vs, respectively. By contrast, p-type dopants boron, aluminum, and gallium exhibit charge carrier mobilities of 450 cm²/Vs, 200 cm²/Vs, and 250 cm²/Vs, respectively. A multi-functional layer 228 of InGaAsP has a charge carrier mobility of approximately 6500 cm²/Vs, while InP has a charge carrier mobility of approximately 5400 cm²/Vs. Thus, by forming the metallic contacts 230B on top of the multi-functional layer 228 instead of the p-type doped semiconductor layer 226, the electrical conductivity of the device can be improved.

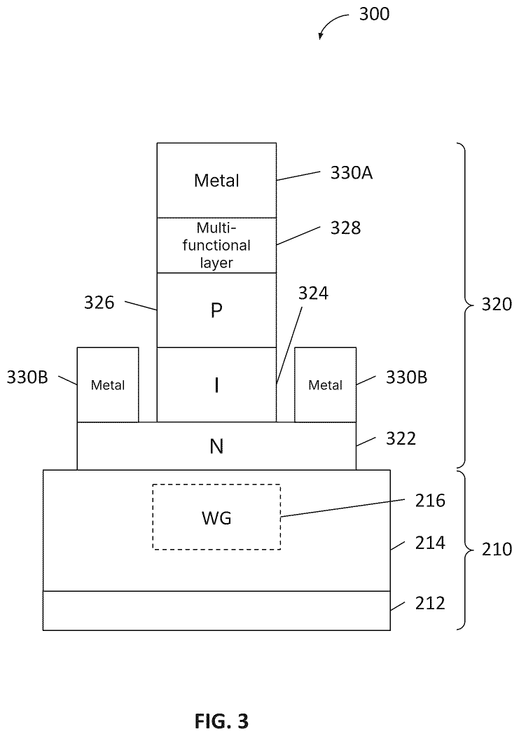

FIG. 3 illustrates a side elevation view of the epitaxial structure of an integrated photonic device 300 in an n-down configuration in accordance with some embodiments of the present disclosure. The dimensions of certain features may be exaggerated for illustrative purposes. The epitaxial structure in FIG. 3 includes a photodiode 320 with an n-down epitaxial structure that is supported on top of a photonic waveguide platform 210. In certain embodiments, the photodiode 320 is formed from a molecular die of group III-V material and is heterogeneously integrated onto the photonic waveguide platform 210 as described in more detail below.

In preferred embodiments, the bare die from which photodiode 320 is to be formed may be fabricated independently of the photonic waveguide platform 210 and integrated onto the photonic waveguide platform 210 by heterogeneous integration as described in more detail herein. FIG. 3 illustrates the photodiode 320 after integration onto the photonic waveguide platform 210.

The photodiode 320 includes a PIN junction formed by an n-type doped semiconductor layer 322, an intrinsic layer 324, and a p-type doped semiconductor layer 326. One or more optional layers, such as shielding layers and light-doped layers to prevent leakage current (not shown), may be present in the photodiode 320 without departing from the scope of the present disclosure. The embodiment shown in FIG. 3 is a vertically stacked configuration referred to as “n-down,” with the n-type doped semiconductor layer 322 closest to the waveguide 216. In some embodiments, the n-type doped semiconductor layer 322 is of indium phosphide (InP) doped with an n-type dopant, such as group V elements including phosphorus, arsenic, antimony, bismuth, and lithium. In some embodiments, the p-type doped semiconductor layer 326 is of InP doped with a suitable p-type dopant, such as group III elements including boron, aluminum, gallium, and indium. The intrinsic layer 324 may be of undoped InP.

The multi-functional layer 328, after integration as described herein, is directly on a top surface of the p-type doped semiconductor layer 326. In some embodiments, the material of the multi-functional layer 328 is selected to achieve lattice matching with the semiconductor layer on top of which it is formed.

As described with respect to the embodiment shown in FIG. 2, the bandgap of the multi-functional layer may be configured to target a particular frequency range by manipulating the one or more chemical compositions of the multifunctional layer material. For example, the bandgap energy of a multifunctional layer 328 made of InGaAsP may be correlated to the composition of phosphide (1-y) contained therein. By way of a non-limiting example, it may be desirable to minimize the absorption of photons having wavelengths within the C band (i.e., 1530 nm to 1565 nm). In some examples, it may be desirable to minimize the absorption of photons having wavelengths of approximately 1550 nm. To this end, the composition of InₓGa₁₋ₓAs_{y}P_{1-y} may be varied, for example, by having a composition of P (1-y) in the range of 0.26 to 0.66.

In some embodiments, the multi-functional layer 328 may also function to improve upon the contact resistance of the p-mesa contact 330A, thereby improving the electrical conductivity of the integrated photonic device 300.

In some embodiments, the multi-functional layer 328 may also serve as an etch stop layer during substrate removal. In the n-down epitaxial configuration, the multifunctional layer 328, after heterogeneous integration, is positioned directly below the substrate layer of the die structure on which the photodiode 320 is grown and directly above the p-type semiconductor layer 326. The substrate layer may be removed by a wet etching process where the integrated device is immersed in an aqueous etchant, such as a hydrochloric acid (HCl)-based solution, that is highly selective to the substrate material. An HCl-based etchant, for example, has low selectivity for InGaAsP, thereby allowing a multifunctional layer 328 of InGaAsP to substantially slow or stop the etching process.

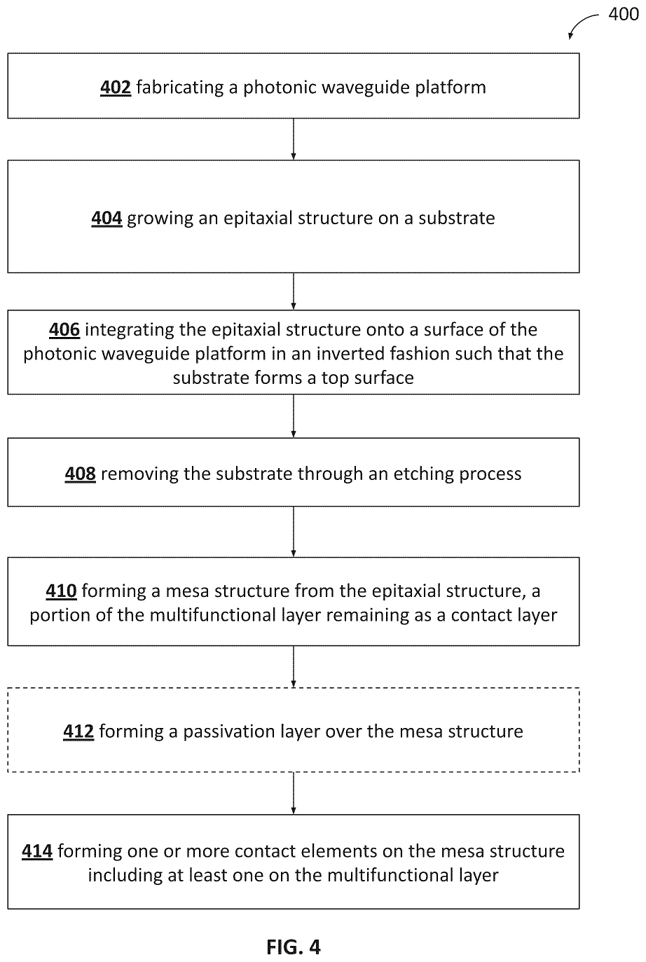

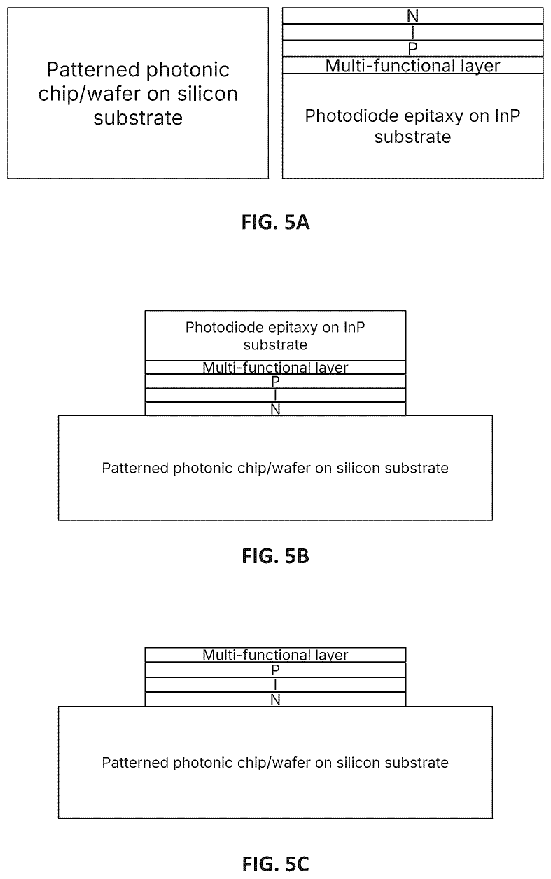

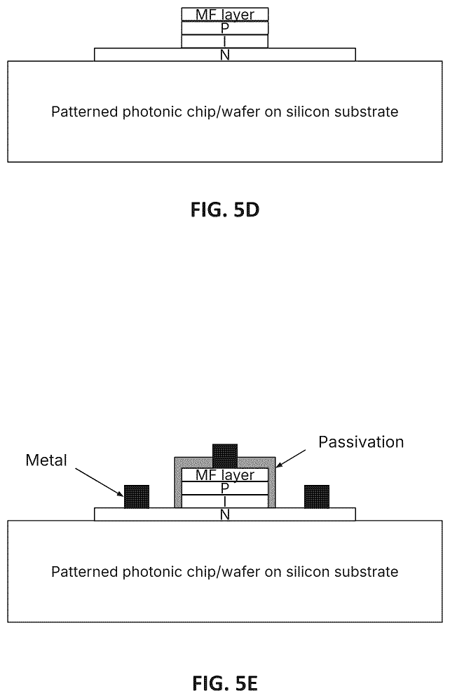

FIG. 4 illustrates a flowchart 400 of a method of manufacturing an integrated photonic device, such as devices 200 and 300 described herein, in accordance with an embodiment of the present disclosure. The method 400 includes fabrication process operations/steps 402 to 414, one or more of which are optional as described in more detail below. FIG. 4 is described in conjunction with FIGS. 5A-5E, which illustrate high-level conceptual illustrations of a photodiode device in accordance with the present disclosure at various stages of method 400.

Step 402 includes fabricating a photonic waveguide platform, such as a semiconductor chip or wafer 210. In some embodiments, the wafer fabrication may include layer deposition where one or more semiconductor layers of one or more semiconductor materials are deposited onto a substrate material/layer. The epitaxial semiconductor layers may be deposited via suitable means, such as chemical vapor deposition, physical vapor deposition, or other deposition methods. In some embodiments, the semiconductor wafer may be a TFLN wafer, which has shown preferred operational characteristics for electro-optic applications.

One or more optical waveguides may be formed within a semiconductor cladding layer of the photonic waveguide platform that are configured to facilitate optical signal propagation. The waveguides may be configured to direct the optical waveguides towards a photodiode, such as photodiodes 220 and 320, by any suitable means such as through adiabatic tapering or grated coupling.

In some embodiments, the semiconductor wafer may be patterned with the desired circuit pattern applied to the wafer via any suitable means such as lithography, including projection optical lithography. By way of a non-limiting example, the wafer may be coated with a photosensitive polymer film known as a photoresist. The circuitry design pattern is transferred onto an opaque mask. Via optical lithography methods, the mask pattern is projected onto the photoresist, where areas of exposed photoresist are chemically altered to become susceptible to etching. Etching may be performed by dry etching and/or wet etching. Dry etching methods may include ion beaming etching (IBE), reactive ion etching (RIE), and inductively coupled plasma (ICP) etching, and may be used for anisotropic etching (i.e., etching in a specific direction). Wet etching methods may include any etching process where the patterned wafer is sprayed or immersed into a chemical solution, or an etchant, to selectively remove portions of the semiconductor layers by chemical reaction with the material of the exposed portions of one or more of the semiconductor layers. Wet etching may be used to perform isotropic etching (i.e., etching in all directions). There may be additional optional steps of surface cleaning and preparation including, but not limited to, passivation, planarization, and metalization. One or more of the semiconductor fabrication methods above may be repeated one or more times.

At step 404, an epitaxial structure that is to be fabricated into the photodiode 220, 320 is grown. In some embodiments, the epitaxial structure may be formed separately from the semiconductor wafer fabrication step 402. Accordingly, in some embodiments, step 404 may be performed before, after, or concurrently with step 402. The epitaxial structure includes a plurality of semiconductor layers grown on a substrate via epitaxy or deposited via suitable means, such as chemical or physical vapor deposition. The semiconductor layers include a multi-functional layer 228, 328, and the layers can be arranged in any one of a p-down or n-down configuration with multifunctional layer 328 grown directly below the p-type semiconductor layer. The semiconductor layers of the epitaxial structure correspond to the layers of the photodiode without the metal contacts 230, 330, but are grown in reverse order from that of the photodiode. FIG. 5A shows a patterned photonic chip/wafer (left) and an independently fabricated epitaxial structure (right) at the end of steps 402 and 404.

In some embodiments, layers of the epitaxial structure may be grown in an n-down configuration, as shown in FIGS. 5A-5E. In an n-down configuration epitaxial structure, the n-type doped semiconductor layer 322 is to be grown as the top layer and the multi-functional layer 328 is to be grown directly above the substrate. The material of the multi-functional layer 328 is a III-V material chosen with high selectivity in favor of the substrate material and the one or more semiconductor layers above it during etching. By way of a non-limiting example, for a substrate material and semiconductor layers of InP, the multi-functional layer 328 may be formed of InGaAsP.

In some other embodiments, the epitaxial structure may be grown in a p-down configuration where the p-type doped semiconductor layer 222 is to be grown as the top epitaxial layer and the multi-functional layer 228 is to be grown between the p-type semiconductor layer 222 and intrinsic layer 224.

At step 406, the epitaxial structure from step 404 is integrated onto the photonic waveguide platform from step 402 as shown in FIG. 5B. The integration may be carried out via heterogeneous integration, a technique commonly used to connect multiple PICs or photonic chips from different material technologies into one single package. Heterogeneous integration is typically performed at the packaging stage after the fabrication of the individual components. This integration process permits concurrent component manufacturing and further allows modular testing and characterization of each component before the integration process. In some embodiments, the epitaxial structure is integrated onto the photonic waveguide platform by bonding it in an inverted fashion. For example, as shown in FIG. 5B, the epitaxial structure is bonded with its substrate as the top layer onto a top surface of the photonic waveguide platform. The integration may be performed by any suitable method such as direct bonding or adhesive bonding. In embodiments where adhesive bonding is applied, the method may include the deposition of an intermediate layer coating onto the photonic waveguide platform 210. For example, a layer of benzocyclobutene (BCB) polymer or SU-8 may be spin coated onto the top surface of the substrate portion to act as the bonding agent. Optionally, following the spin coating, the bonding agent intermediate layer may be soft baked at temperatures of up to approximately 100° C. to remove any excess solvents. The epitaxial structure may then be brought into physical contact with the top surface of the photonic waveguide platform. The entire integrated device may be fully cured after or during bonding by a hard baking process with an elevated baking temperature ranging from 110 to 220° C. In direct bonding, the optional bonding agent layer is obviated, and the epitaxial structure and the substrate portion are bonded at temperatures between approximately 120 and 300° C.

At step 408, the substrate layer on top of the heterogeneously integrated device, or the substrate layer on which the epitaxial structure was formed, is removed through an etching process. In some embodiments, the substrate layer has a thickness of >100 μm. Its etching may be performed by one or more of a dry etching process, a wet etching process, an anisotropic etching process, an isotropic etching process, or other suitable processes. For example, etching of the integrated photonic device 300 may be done through wet etching using a hydrochloric acid (HCl)-based etchant. A substrate layer, such as the InP substrate layer shown in FIG. 5A, upon which the photodiode 320 is formed may be vertically etched down to the multi-functional layer 328 such that the multifunctional layer becomes the top layer, as illustrated in FIG. 5C. Since the wet etchant acts only on the substrate material, e.g., InP, the multi-functional layer 328 may act as an etch stop layer that accurately stops the etching process and ensures the structural integrity of the semiconductor layers beneath. Compared to typical etch stop layers made from materials such as InGaAs, a multi-functional layer made from InGaAsP has several advantages. For photonic applications, InGaAs has a propensity to absorb light with wavelengths near 1550 nm with an absorption coefficient of 6000 cm⁻¹ to 7000 cm⁻¹ and resulting carriers generated in this layer are difficult to collect, leading to elevated signal loss. In direct contrast, InGaAsP has a much higher bandgap compared to InGaAs for 1550 nm wavelength light with an absorption coefficient of approximately 600 cm⁻¹, thereby minimizing photonic absorption at the desired wavelength range.

Due to its optical inefficiency, a traditional InGaAs etch stop layer would need to be removed (e.g., via dry etching, wet etching, or a combination of dry and wet etching) upon removal of the substrate, further complicating the fabrication process. In contrast, a multi-functional layer made of InGaAsP could be maintained after substrate removal as it does not negatively impact the signal loss.

By way of an example, for an embodiment where a wet etching technique is applied, an InP substrate of the III-V epitaxial structure may be removed through wet etching with a hydrochloric acid (HCl) etchant (e.g., H₃PO₄:HCl=3:1), which has high selectivity in favor of an InP substrate layer. As shown in FIG. 5C, upon removal of the substrate, the multi-functional layer 328 is now the top semiconductor layer with the one or more semiconductor layers below maintained intact. The InGaAsP multi-functional layer is maintained and functions as a contact layer for the photodiode device.

As stated, in some embodiments, the substrate removal may be performed through dry etching techniques, such as plasma treatment with an InGaAs etch stop layer. Dry etching may be preferred in certain applications as it offers high selectivity and machining shape control. However, dry etching techniques may require longer processing times and equipment that is more specialized and cost prohibitive.

At step 410, the epitaxial portion of the photodiode device is further etched to form one or more mesa structures through mesa etching. Mesa etching may be done through any suitable methods of wet chemical etching, gas plasma etching, or a combination of the two. The mesa etching process may involve one or more iterations of photoresist mask deposition, application of etchant, and mask removal until a desired mesa profile such as that of the photodiode shown in FIG. 5D is achieved. In some embodiments, the mesa structure has a step height of <10 μm. For example, following lithography patterning of the epitaxial layer, the device may be submerged in a chemical enchant such as an HCl etchant. With a known etch rate of the etchant, the duration of the etching process can be timed accordingly.

Optionally, at step 412, a passivation layer may be formed over portions of the mesa structure as shown in FIG. 5E. Passivation of a semiconductor device refers to a step by which a semiconductor surface is rendered inert without altering the device properties when it interacts with air or other materials. The passivation layer may be formed of a dielectric material such as undoped silicate glass (USG), silicon nitride, silicon oxide, or any other low-index material by any suitable methods such as chemical vapor deposition, physical vapor deposition, or the like. One or more openings through the passivation layer may be patterned to expose one or more contact pad areas on the multi-functional layer. Advantageously, the InGaAsP could further function to improve the electrical conductivity of any metallic contact, such as contact 330A in FIG. 3, deposited thereon. For example, InGaAsP may have a charge carrier mobility of approximately 6500 cm²/Vs, while InP may have a charge carrier mobility of approximately 5400 cm²/Vs.

At step 414, one or more contact elements are formed on the mesa structure including at least on the multi-functional layer. For example, as shown in FIG. 3, contact 330A is formed on the multi-functional layer 328 as the p-type terminal and contacts 330B are formed on the n-type doped semiconductor layer as the n-type terminal of the integrated photonic device 300. In embodiments where a passivation layer is present, the one or more contact elements are formed over one or more openings patterned into the passivation layer such that the contacts form an electrically conductive connection with the layer beneath. The contact elements may be made of Au or Cu structures, or another conductive material such as tin/lead (SnPb), copper/zinc (CuZn), or copper/silver (CuAg) solder, with each optionally containing a flux material. The solder material may be deposited using a ball drop, stencil printing, and/or plating process.

Although the present disclosure may describe methods and processes with steps in a certain order, one or more steps of the methods and processes may be omitted or altered as appropriate. One or more steps may take place in an order other than that in which they are described, as appropriate.

Although the present disclosure may be described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A photodiode comprising:
a first layer of a first type semiconductor;
a second layer of a second type semiconductor;
a third intrinsic layer between the first and second layers; and
a fourth multifunctional layer formed above the first layer, wherein the fourth multifunctional layer (1) functions as a contact layer between the first layer and one or more metal contacts and (2) is configured to minimize photon absorption at a target wavelength range.

2. The photodiode of claim 1, wherein a material of the fourth multifunctional layer is one of InGaAsP and InGaAsAl.

3. The photodiode of claim 2, wherein the composition of phosphorus (P) or aluminum (Al) in the fourth multifunctional layer material is configured to achieve the target wavelength range.

4. The photodiode of claim 1, wherein the first and second layers are arranged in an n-down structure, and the fourth multifunctional layer also serves as an etch stop layer during a wet etching process.

5. The photodiode of claim 1, wherein the target wavelength range includes 1260 nm to 1625 nm.

6. The photodiode of claim 1, wherein the fourth multifunctional layer maintains a lattice match with the first layer.

7. The photodiode of claim 1, wherein the first type semiconductor is a p-type doped semiconductor material and the second type semiconductor is an n-type doped semiconductor material.

8. The photodiode of claim 1, wherein the photodiode is coupled to a photonic waveguide platform, and the photonic waveguide platform includes a waveguide formed therein configured to direct a photonic signal towards the photodiode.

9. The photodiode of claim 8, wherein the photodiode is a III-V semiconductor mesa structure bonded on a top surface of the photonic waveguide platform.

10. The photodiode of claim 1, wherein the first and second layers are arranged in a p-down structure.

11. A method comprising:
fabricating a photonic waveguide platform;
growing an epitaxial structure on a substrate, the epitaxial structure having a first semiconductor layer, a second semiconductor layer, a third intrinsic layer between the first and second semiconductor layers, and a fourth multifunctional layer directly below the first semiconductor layer, the fourth multifunctional layer configured to minimize photon absorption at a target wavelength range;
integrating the epitaxial structure onto a surface of the photonic waveguide platform in an inverted fashion such that the substrate forms a top surface;
removing the substrate through an etching process;
forming a mesa structure from the epitaxial structure, a portion of the multifunctional layer remaining as a contact layer; and
forming one or more contact elements on the mesa structure including at least one contact element on the multifunctional layer, the multifunctional layer functioning as a contact layer.

12. The method of claim 11, wherein the growing includes forming the fourth multifunctional layer out of one of InGaAsP and InGaAsAl.

13. The method of claim 11, wherein the growing includes forming the fourth multifunctional layer directly above the substrate, the etching process is a wet etching process, and the fourth multifunctional layer functions as an etch stop.

14. The method of claim 11, further comprising forming a passivation layer over the mesa structure prior to the forming of the one or more contact elements.

15. The method of claim 11, wherein the growing further includes:
forming the first semiconductor layer with a first type semiconductor; and
forming the second semiconductor layer with a second type semiconductor.

16. The method of claim 15, wherein the first type semiconductor is a p-type semiconductor and the second type semiconductor is an n-type semiconductor.

17. The method of claim 11, further comprising forming a waveguide in the photonic waveguide platform, wherein the waveguide is configured to direct a photonic signal towards the epitaxial structure.

18. The method of claim 11, further comprising configuring a chemical composition of the multifunctional layer to achieve the target wavelength range.

19. The method of claim 11, wherein the target wavelength range includes 1260 nm to 1625 nm.

20. The method of claim 11, wherein the growing includes forming the second semiconductor layer directly above the substrate.
